(19) United States
(12) Patent Application Publication
(10) Pub. No.: US 2005/0029675 A1
(43) Pub. Date: Feb. 10, 2005

(54) Tin/indium lead-free solders for low stress chip attachment

(76) Inventor: Fay Hua, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/933,966

(22) Filed: Sep. 3, 2004

Related U.S. Application Data
(63) Continuation-in-part of application No. 10/404,695, filed on Mar. 31, 2003.

(51) Int. Cl. H01L 21/44; H01L 23/48; H01L 29/40

(52) U.S. Cl. 257/779; 257/784; 438/612

(57) ABSTRACT

Some embodiments of the present invention include lead-free solders for use in low stress component attachments.

### CLAIM OF PRIORITY

This application is a continuation-in-part of and claims priority to U.S. patent application Ser. No. 10/404,695 filed on Mar. 31, 2003 entitled “PHASE CHANGE LEAD-FREE SUPER PLASTIC SOLDERS,” which is incorporated herein by reference in its entirety.

### FIELD OF THE INVENTION

The field of invention relates generally to soldering processes and, more specifically but not exclusively relates to lead-free solders.

### BACKGROUND INFORMATION

Solders are special composition metals (known as alloys) that, when in the presence of flux, melt at relatively low temperatures (120-450° C.). The most commonly used solders contain tin and lead as base components. Many alloy variations exist that include two or more of the following metallic elements: tin (Sn), lead (Pb), silver (Ag), bismuth (Bi), antimony (Sb) and copper (Cu). Solder works by melting when it is heated, and bonding (wetting) to metallic surfaces. The solder forms a permanent intermetallic bond between the metals joined, essentially acting like a metal “glue.” In addition to providing a bonding function, solder joints also provide an electrical connection between soldered components and a heat transfer path. Solders are available in many forms including paste, wire, bar, ribbon, preforms and ingots.

Many high-density integrated circuits (ICs), such as microprocessors, graphics processors, microcontrollers, and the like are packaged in a manner that use of a large number of I/O lines. Common packaging techniques employed for this purpose include “flip chip” packaging and ball grid array (BGA) packages. Both of these packaging techniques employ solder connections (joints) for each I/O line (e.g., pin or ball). In conjunction with the ever-increasing density of complex ICs, a corresponding increase in the I/O connection density of flip chip and BGA has occurred. As a result, the solder joints employed in the packages have had to be reduced in size.

More specifically, Flip Chip (FC) is not a specific package (like SOIC), or even a package type (like BGA). Flip chip describes the method of electrically connecting the die to the package carrier. The package carrier, either substrate or leadframe, then provides the connection from the die to the exterior of the package. In “standard” packaging, the interconnection between the die and the carrier is made using wire. The die is attached to the carrier face up, then a wire is bonded first to the die, then looped and bonded to the carrier. Wires are typically 1-5 mm in length, and 25-35 μm in diameter. In contrast, the interconnection between the die and carrier in flip chip packaging is made through a conductive “bump” that is placed directly on the die surface. The bumped die is then “flipped over” and placed face down, with the bumps connecting to the carrier directly.

The flip chip connection is generally formed in one of two ways: using solder or using conductive adhesive. By far, the most common packaging interconnect is solder, high 97Pb-3Sn at die side and attached with eutectic Pb—Sn to substrate. The solder bumped die is attached to a substrate by a solder reflow process, very similar to the process used to attach BGA balls to the package exterior. After the die is soldered, underfill is added between the die and the substrate. Underfill is a specially engineered epoxy that fills the area between the die and the carrier, surrounding the solder bumps. It is designed to control the stress in the solder joints caused by the difference in thermal expansion between the silicon die and the carrier, as described in further detail below. Once cured, the underfill absorbs much of the stress, reducing the strain on the solder bumps, greatly increasing the life of the finished package. The chip attach and underfill steps are the basics of flip chip interconnect. Beyond this, the remainder of package construction surrounding the die can take many forms and can generally utilize existing manufacturing processes and package formats.

Recently, the European Union has mandated that no new products sold after Jun. 30, 2006 contain lead-based solder. Other counties and regions are considering similar restrictions. This poses a problem for manufactures of IC products, as well as for other industries that employ soldering processes during product manufacture. Although many Pb-free solders are well-known, these solders have properties that make them disadvantageous when compared with lead-based solders, including reduction in ductility (plasticity). This is especially problematic in flip-chip and BGA assembly processes.

Owing to active R & D efforts, substantial progress toward a full transition to Pb-free soldering technology has been made recently. At present, the leading candidate solders are near-ternary eutectic Sn-Ag-Cu alloys for various soldering applications. The near-eutectic ternary Sn-Ag—Cu alloys yield three phases upon solidification, β-Sn, Ag₃Sn and Cu₆Sn₅. During solidification, the equilibrium eutectic transformation is kinetically inhibited. While the Ag₃Sn phase nucleates with minimal undercooling, the β-Sn phase requires a typical undercooling of 15 to 30° C. for nucleation. As a consequence of this disparity in the required undercooling, large, plate-like Ag₃Sn structures can grow rapidly within the liquid phase, during cooling, before the final solidification of solder joints. When large Ag₃Sn plates are present in solder joints, they may adversely affect the mechanical behavior and possibly reduce the fatigue life of solder joints by providing a preferential crack propagation path along the interface between a large Ag₃Sn plate and the β-Sn phase. Further problems common to Sn—Ag—Cu solders include ILD (inner layer dielectric) cracking and pad peel off at the substrate for flip chip assemblies, poor reliability, and pad peel off at the BGA side for BGA packages.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIGS. 1a-1c are cross-section views illustrating a conventional flip-chip assembly process, wherein FIG. 1a illustrates a condition at a solder reflow temperature, FIG. 1b illustrates a condition after the assembly has cooled, and FIG. 1c illustrates a condition after an underfill is added and a cap is molded over the assembly;

FIG. 2 is a phase diagram corresponding to an Sn—In alloy;

FIG. 3 is a schematic diagram illustrating a change in lattice structure for an Sn—In alloy as it cooled from a high temperature to a low temperature;

FIG. 4 is a graph illustrating relative percentage of the phase change vs. temperature and Sn—In weight ratios;

FIG. 5 is a microscopic scan illustrating formation of Martensite for an Sn-7In allow that is air cooled;

FIG. 6 is a microscopic scan illustrating results of a martensitic phase transformation for Sn-9In that was formed under a compression stress; and

FIG. 7 is a graph illustrating displacement characteristics of Silicon (Si) and Sn-7In vs. temperature under a typical cooling rate;

FIG. 8 is a cross-section view illustrating an apparatus in accordance with one embodiment of the present invention.

FIGS. 9A and 9B are cross-section views illustrating a method in accordance with one embodiment of the present invention.

FIGS. 10A and 10B are cross-section views illustrating a method in accordance with one embodiment of the present invention.

### DETAILED DESCRIPTION OF PREFERRED EMBODIMENTS

Details of lead-free solder compositions and exemplary uses for the solders are described herein. In the following description, numerous specific details are set forth, such as implementing the lead-free solder for flip-chip packaging, to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

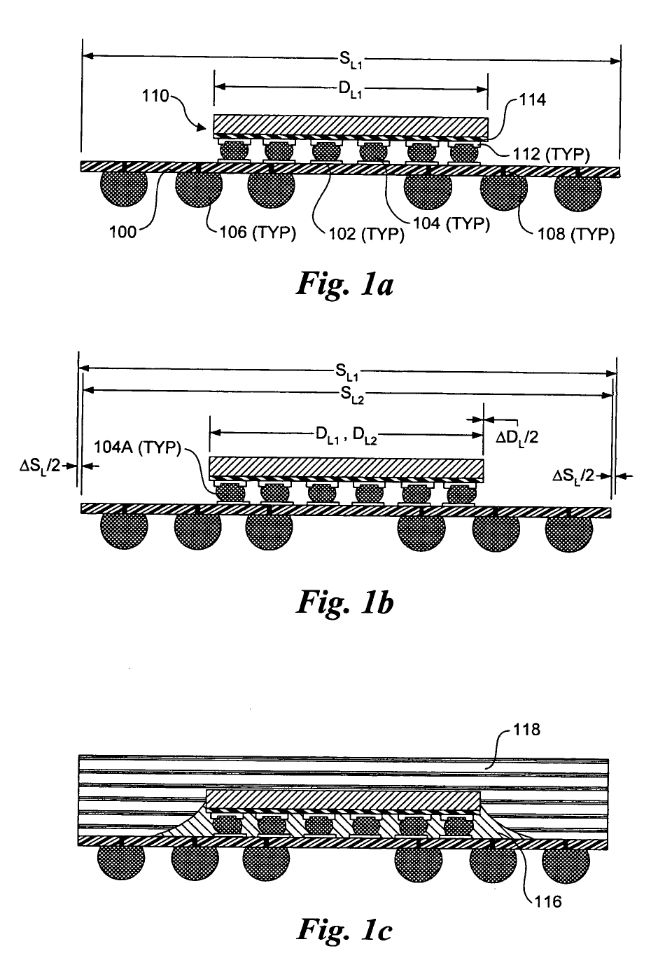

With reference to FIGS. 1a and 1b, a typical flip-chip assembly includes a substrate 100 having a plurality of pads 102 on which respective solder bumps 104 are formed. Substrate 100 further includes a plurality of solder balls 106 coupled to its underside. Respective leads 108 are routed between each pad 102 and solder ball 106. An integrated circuit die 110 is “flip-chip” mounted to substrate 100 by means of solder bumps 104. To facilitate electronic connections to the die circuitry, die 110 includes a plurality of pads 112 mounted to it underside, each of which are connected to a respective portion of the die circuitry via electrical lines (not shown) passing through an inner layer dielectric (ILD) 114. The ILD typically comprises a dielectric layer that is formed over the die substrate, such as silicon dioxide for a silicon die substrate. In order to increase the operational speed of the die, low k materials may be used for the ILD. However, many low k materials may be mechanically weak.

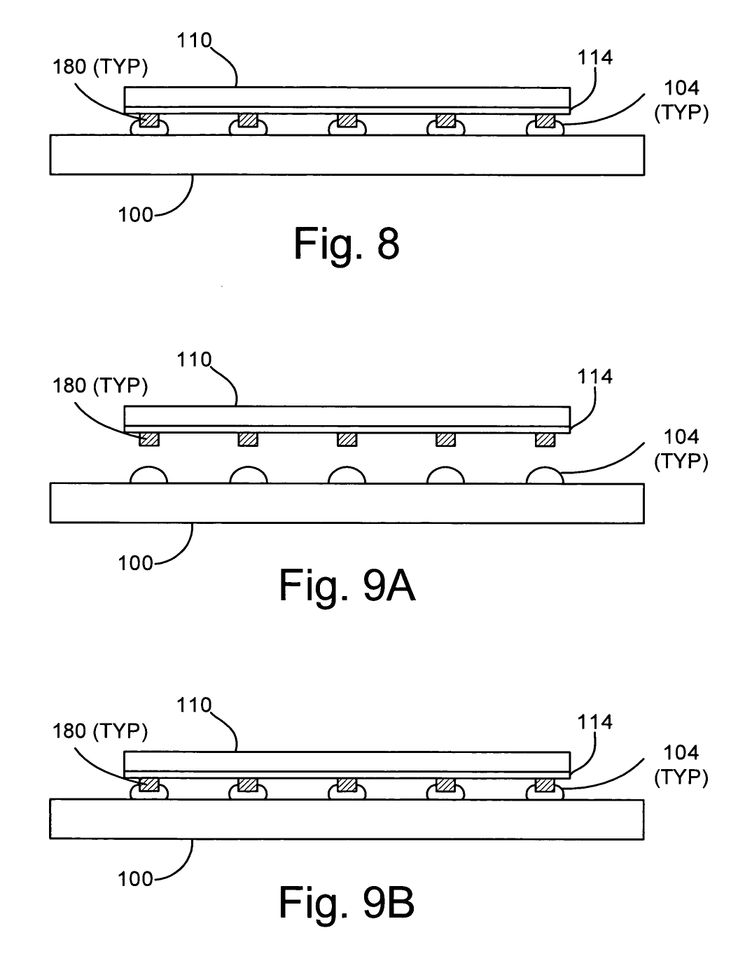

In another flip-chip assembly, illustrated in FIG. 8, the flip-chip assembly may include a die 110 with a plurality of conductive contacts 180. The conductive contacts 180 may be formed on the die 110 by a controlled collapsed chip connect process, electroplating process, or other process, and may be any suitable conductive material. In one embodiment, the conductive contacts 180 may be copper. The conductive contacts 180 may be conductively coupled to solder bumps 104 to provide electrical connection between the die 110 and the substrate 100. Substrate 100 may include connections on its bottom surface (not shown) analogous to the solder balls 106 of FIG. 1a. The connections may also be pins or columns or other structure for connection to a circuit board.

The flip-chip components are assembled by raising the temperature of the solder bumps until the solder's reflow temperature is reached, causing the solder bumps to melt. This is typically performed in a reflow oven or the like. Subsequently, the assembled components are cooled, resulting in reversion of the solder back to its solid state, thereby forming a metallic bond.

In one method, the flip-chip assembly of FIG. 8 may be assembled in a manner illustrated in FIGS. 9A and 9B. FIG. 9A shows a die 110 having conductive contacts 180 distributed on its active surface that may be electrically connected to die circuitry (not shown). In one embodiment, the conductive contacts 180 may be copper. Substrate 100 includes solder bumps 104 which may be connected to leads and connections on a bottom surface (not shown) analogous to those shown in FIG. 1a. The solder bumps 104 may be heated to a temperature above the reflow temperature of the solder and the components may be contacted such that the conductive contacts 180 are in contact with corresponding solder bumps 104 as illustrated in FIG. 9B. The solder may then be cooled to form metallic bonds.

Typically, the substrate will be formed of a rigid material, such as a rigid laminate. Meanwhile, the die and inner layer dielectric are typically formed from a semiconductive substrate, such as silicon. Silicon has a typical coefficient of thermal expansion (CTE) of 24 parts per million (ppm) per degree Celsius. The CTE for a typical flip-chip substrate is approximately 16-19 ppm/° C. This difference in CTE's leads to induced stresses in the solder bumps and inner layer dielectric, as follows.

At the reflow temperature, the substrate and die have respective relative length S_{L1} and D_{L1} in accordance with that shown in FIG. 1a. As the assembly is cooled, the relative lengths are reduced, as shown by lengths S_{L2} and D_{L2} in FIG. 1b. The respective reductions in length are depicted as ΔS_{L} and ΔD_{L}, wherein ADL is shown as substantially 0 for clarity. Since the CTE for the die is much less than the CTE for the substrate, ΔS_{L} is much greater than ΔD_{L}.

As a result of the CTE mismatch, solder bumps 104 are caused to elongate, as shown by solder bumps 104A in FIG. 1b. For example, consider the configuration of the solder bumps when the assembled components are cooled to a temperature just below the reflow temperature. At this point, the length of the components is substantially the same as that for the reflow configuration of FIG. 1a. The solder is in a solid state, although it is fairly ductile due to the elevated temperature. The solidified solder of each solder bump adheres to respective pairs of pads 102 and 112. As the cooling of the components continues, the length of substrate 100 is reduced by a greater amount than the length of die 110. As a result, the solder bumps are caused to be elongated (strained), inducing a stress in the solder material. Additionally, a portion of the stress is transferred through pads 112 to ILD 114.

Also, die 110 generates heat during operation in correspondence with resistance losses in its circuitry. As a result, the temperature of the die, as well as nearby thermally-coupled components including substrate 100, may increase. When the die circuitry is operating under a high workload condition, its temperature is higher, while lower workload operations result in a lower temperature, and of course no operation results in a still lower temperature. As a result, operation of the die circuitry induces thermal cycling and corresponding stress cycling on the solder bumps due to the CTE mismatch.

The stresses caused during assembly and operation may lead to failure conditions, such as pad peel off, ILD cracking, and ILD/conductive line delamination.

One technique commonly used to reduce the thermal cycling stress-related failures is to fill the volume proximate to solder bumps 104 with an epoxy underfill 116, as shown in FIG. 1c. The packaging process is usually then completed by molding a cap 118 over the top of the various assembly components. When an underfill is employed in this manner, the operational stress load is placed across the cross section of the combination of the solder bump/pad interfaces and the underfill rather than just the solder bump/pad interfaces alone. This reduces the stress on the bulk solder and solder bump/pad interfaces to some degree, but doesn't entirely remove the stress. Further, there is no underfill during the chip attachment process and the CTE induced stress during chip attachment may be absorbed mainly by the solder bumps 104. If the solder bumps 104 are stiff, the ILD may crack during the chip attachment process.

One method for applying the underfill 116 illustrated in FIG. 1c may be to use a capillary underfill material. A capillary underfill may be applied around the edge gap between the die 110 and the substrate 100. The capillary underfill may then flow into the entire gap to provide an underfill 116 as illustrated in FIG. 1c. The capillary underfill method may also be used to provide an underfill (not shown) to the flip-chip assembly illustrated in FIG. 8. The capillary underfill material may help protect the ILD during reliability testing, but not during the assembly process since the underfill is applied after assembly.

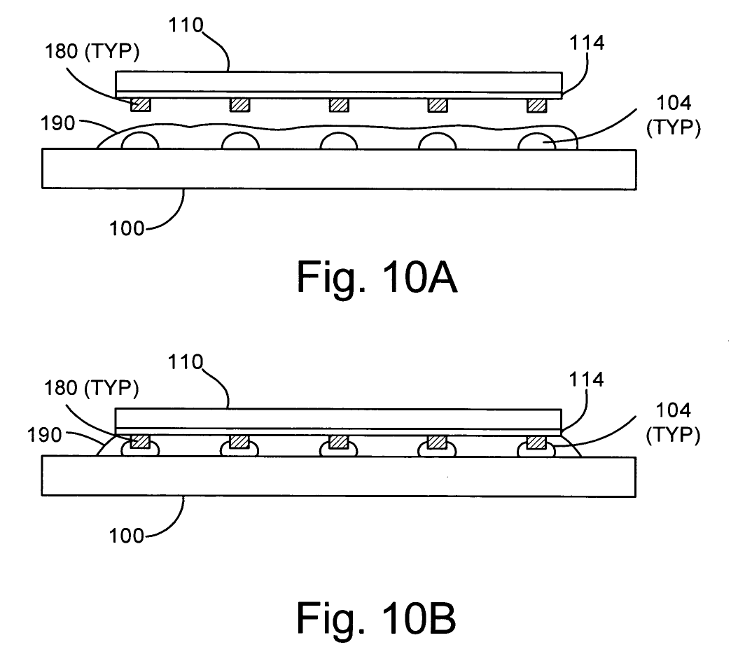

In another method, a no-flow underfill material may be used, as illustrated in FIGS. 10A and 10B. In FIG. 10A, the no-flow underfill 190 may be applied onto the substrate 100 and may immerse the solder bumps 104. The die 110, including conductive contacts 114, and the substrate 100, including solder bumps 104 and no-flow underfill 190, may be heated to a processing temperature above the melting point of the no-flow underfill and reflow temperature of the solder. The components may be brought into contact, as illustrated in FIG. 10B, and cooled so that electrical contacts are made between conductive contacts 180 and solder bumps 104 and no-flow underfill 190 is adjacent to the electrical contacts, die 110, and substrate 100.

Under prior manufacturing techniques, solder bumps 104 would typically comprise a lead-based solder, such as those discussed above. Such solders generally exhibit good plasticity (are very ductile) throughout the temperature ranges the package components are typically exposed to. As a result, failure due to pad peel-off and ILD cracking are fairly uncommon.

However, the use of lead-based solders is not a viable option henceforth for many manufactured products, such as products designated for sale to EU countries. Thus, the solder bumps for these products must comprise a lead-free material. As discussed above, Sn—Ag—Cu alloys have become the leading candidate solders for replacing lead-based solders. This leads to problems in many applications, since Sn—Ag—Cu solders do not exhibit good plasticity when compared with lead-based solders, leading to the failure modes discussed above.

Phase Change Lead-Free Super Plastic Solders

In accordance with principles of the invention, a lead-free solder compound with super plasticity is disclosed. In one embodiment, the lead-free solder comprises a Sn—In alloy, wherein the weight % ratio, wt. % is 4-15% indium (85-96 wt. % Sn). The super plasticity is due to a phase change in the Sn—In alloy as it is cooled from its reflow temperature to room temperature. This phase change dramatically reduced the residual stress problem associated with flip-chip assemblies and the like.

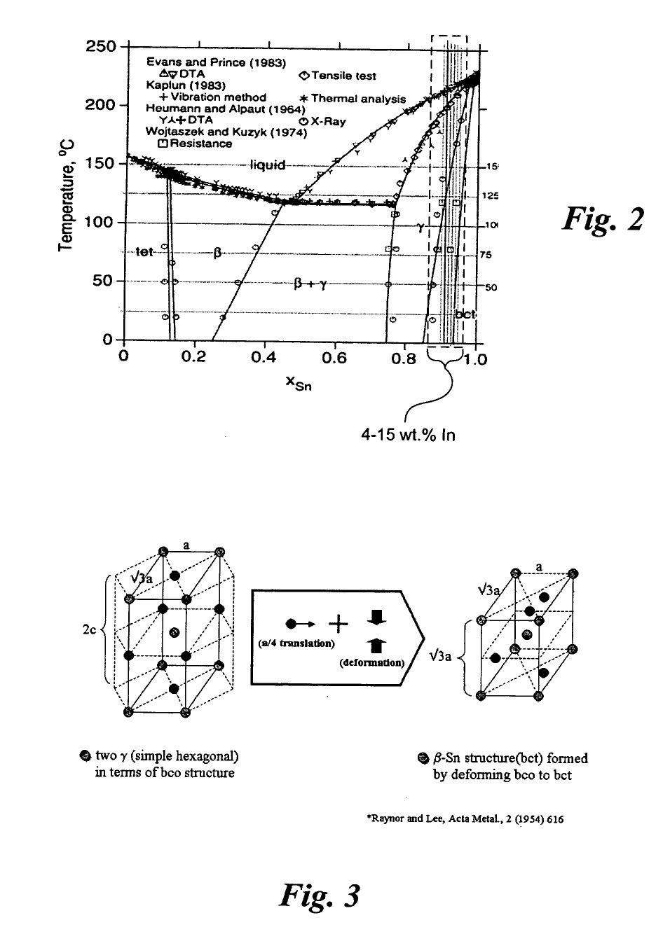

FIG. 2 is phase diagram of Sn—In alloy system. When the ratio of In to Sn is 4-15% wt. %, there is a high temperature packed hexagonal 7 phase to lower temperature β-Sn bct (body-centered tetragonal) transition. It has been demonstrated that the phase transformation can happen as a Martensite transformation (Y. Koyama, H.suzuki and 0. Nittono, Scripta Metallurgica, vol. 18, pp.715-717, 1984). It has been realized by the inventor that this Martensite transformation is an advantageous feature of 4-15% wt. % Sn—In alloys with regard to it use for solder joints. More specifically, in accordance with the Martensite transformation, the bulk solder will elongate in a manner that compensates for the CTE mismatch between joined components, such as a die and substrate, with minimum introduction of stress in the solder joints. Furthermore, a reduction in the stress in the inner layer dielectric will also result. These improved solder characteristics lead to increased package reliability.

A schematic diagram illustrating the phase change at the molecular level is shown in FIG. 3. At higher temperature, the Sn—In alloy lattice structure corresponds to the packed hexagonal γ phase bco (body-centered orthorhombic) structure 300. In this structure, the corners of each plane are alternately occupied by Sn atoms 302 (light colored) and In atoms 304 (dark colored). The atoms are separated along one planel axis by a distance “a” and along the other planel axis by a distance of √3a. The planes are separated by a distance “c”; thus the distance between Sn planes is 2c. As the alloy cools, a phase transformation from γ phase bco structure 300 to a β-Sn bct (body-centered tetragonal) structure 306 occurs. This results from a translation of In atoms relative to the Sn atoms of a/4. At the same time, the distance between the planes is decreased, such that the distance between two Sn planes is reduced to √3a. This results in a shortening of the lattice structure in one direction, and a lengthening in a perpendicular direction.

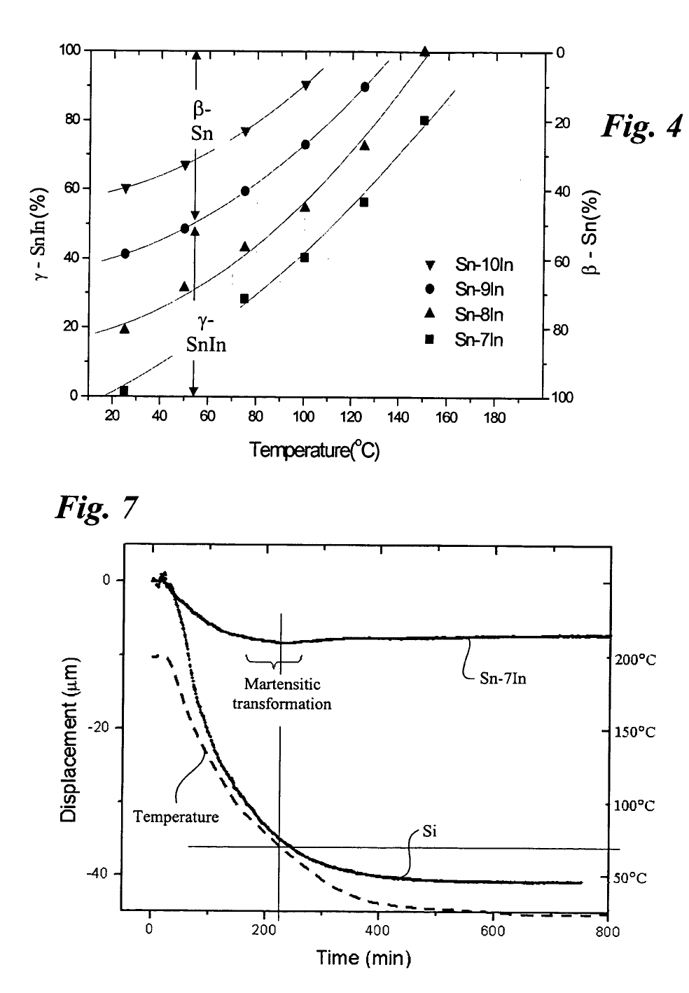

FIG. 4 shows the phase-transformation behavior of several Sn—In alloys over a normal cooling range. As the temperature is lowered, more γ bco phase transfers to β-Sn bct phase. It is further noted that as the wt. % In is decreased, the percentage of phase transformation at a given temperature increases. As a result, the plasticity behavior of a particular Sn—In alloy can be tailored to suit a targeted application in which it is to be used.

Further aspects of the invention relate to a Martinsite transformation that occurs when the alloy is cooled. In general, Martinsite and “martensitic” transformations concern diffusionless crystallographic changes that are used to change the material properties of alloys. German metallographier A. Martens was the first to identify such a crystallographic change in iron-carbon steels, and thus Martensite is named after him.

Depending on the type of martensitic transformation, which is generally dependent upon the alloyed elements and/or heat treatment parameters, martensitic transformation form plates, needles, or leaf-like structures in the new phase. The Martensite structures change the material properties of the alloy. For example, it is common to heat-treat steels to form Martensite on wear surfaces, such as knives and the like. Under this type of use, the martensitic structure comprises a hardened material at the surface of the steel that is very wear-resistant. Although increased hardness is often beneficial, a downside is a loss in ductility: martensitic steels are generally classified as brittle materials (when compared with non-martensitic phases of corresponding steel alloy, such as annealed steel).

Although martensitic steels exhibit brittle (i.e., non-ductile) behavior, other martensitic alloys exhibit substantially different behaviors, including super plasticity. For example, some memory metals (i.e., a class of metals that can be deformed and returned to their undeformed shape) employ a martensitic phase. In this instance, the metallurgical reason for the Martensite deformability is considered to be the “twinned” structure of the phase: the twin boundaries can be moved without much force and without formation of dislocations, which are typically considered to initiate material fracture.

A further advantage of this structure is the material is not prone to strain hardening, which leads to a decrease in ductility over time as a material is exposed to strain cycling. Such cycling occurs as a result of the temperature cycling of the die in the foregoing flip-chip application. Thus, a conventional solder becomes hardened over time, leading to the formation of fatigue cracking and eventual joint failure.

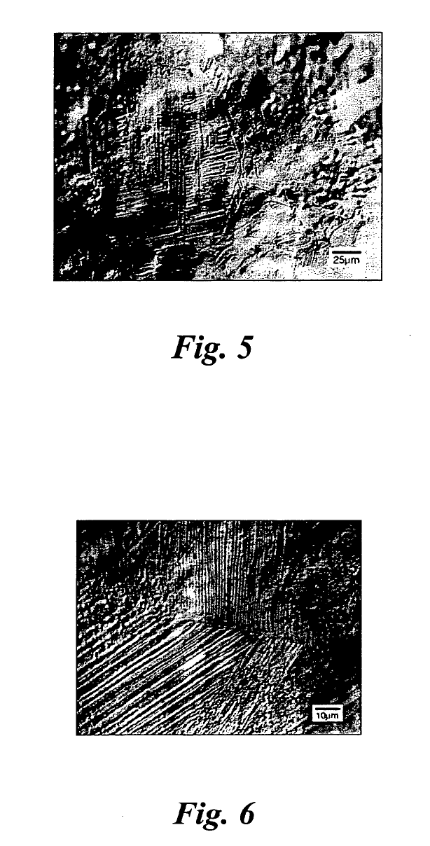

Details of microscopic structures that result from martensitic phase transformations are shown in FIGS. 5 and 6. FIG. 5 shows a microscopic scan of an Sn-7In (i.e., 7 wt. % In) alloy that has been exposed to air cooling. Note the “needle”-like structure shown in the central portion of the scan. FIG. 6 shown a result of a martensitic phase transformation for Sn-9In that was formed under a compression stress. In this case, the direction of the martensitic structure coincides with the material strain.

Displacement characteristics of Silicon (Si) and Sn-7In vs. temperature are shown in FIG. 7. As shown in the figure, the relative displacement of Si substantially mirrors the temperature profile, as would be expected with a constant CTE value. Initially, the Sn-7In alloy exhibits a similar proportional behavior, until the temperature falls through the range of approximately 80-70° C. During this time frame, a martensitic transformation takes place. After the transformation has occurred, the displacement of the Sn-7In alloy remains substantially constant even the temperature continues to be reduced.

The behavior shown in FIGS. 6 and 7 is directly applicable to the flip-chip CTE mismatch problem discussed above. As discussed above, as the assembly is cooled, the CTE mismatch between the die and substrate materials causes a strain to be induced on the solder bumps. This, in turn, results in stresses within the bulk solder material, and more importantly, at the solder bump/pad interfaces. When an Sn—In solder having the weight ratios disclosed herein is used, a martinsitic phase change under stress occurs. Thus, the bulk solder elongates in the direction of the stress as the solder cools, substantially eliminating the residual stress in the solder bumps that result from the CTE mismatch.

In addition to the Sn—In alloy compositions discussed above, these alloys may be altered by adding small amounts of various metals to produce targeted behaviors. For example, small amounts (e.g. <2 wt. %) of Sb, Cu, Ag, Ni, Ge, and Al may be added to further refine the as-cast microstructure and improve thermal stability. The particular wt. % of these metals that is optimal will generally be dependent on the particular application the solder is to be used in. Such factors include solder reflow temperature, plasticity requirements, expected thermal cycling temperature ranges, etc.

The super-plastic solder alloys described herein are not only very ductile, but also resistant to fatigue. Under typical fatigue loading (e.g., cyclical inducement of strain due to temperature cycling), a conventional solder undergoes a change in its structure. This structural change weakens the bulk material over time, eventually leading to failure. In contrast, the deformation of the super-plastic solder alloys due to the phase change mechanism does not cause a similar level of damage to the bulk material. As a result, the super-plastic solder alloys may be successfully employed in application that would normally lead to fatigue failures when implemented with conventional solders.

Lead-Free Solders with Small Grain Microstructures

In another disclosed embodiment, the lead-free solder may be a small grain microstructure Sn—In alloy. A small grain microstructure may have an average grain size of less than about 5 microns across. To form a small grain microstructure Sn—In alloy, a Sn—In alloy may be cooled quickly from above its melting point to room temperature at a rate of about 3 degrees Celsius per second. In one embodiment, the cooling may be done by air cooling. In one embodiment, the Sn—In alloy may comprise about 12 to 18 weight percent In and about 82 to 88 weight percent Sn. Small amounts (less than about 3 weight percent) of other elements, such as Cu, Ag, and Ni, may be added to the alloy. In an embodiment, the alloy may comprise 85 weight percent Sn, 14 weight percent In, and 1 weight percent copper.

When the Sn—In alloy is cooled quickly, small grains may be formed instead of a lattice structure that may be formed when the alloy is cooled slowly. In one embodiment, the Sn—In alloy may be cooled at a rate of greater than about 3 degrees Celsius per second. In such an embodiment, the grains of the small grain microstructures may average about 3 μm across with the largest grains being about 5 μm across.

A small grain microstructure Sn—In alloy may provide outstanding characteristics to provide a low stress attachment and high fatigue resistance for components. The small grain microstructure of the alloy may allow motion about the small grains at grain boundaries when the bulk material is under a stress, giving the material a relatively low yield stress and high fatigue resistance. The small grain microstructure Sn—In alloy may be ductile under stress and may absorb a substantial amount of stress caused by cooling during assembly and temperature cycling during operation and CTE component mismatch as discussed above.

A small grain microstructure Sn—In alloy may also provide outstanding characteristics to electrically connect components, such as between a die and a substrate as illustrated in FIGS. 1 and 8. To provide electrical connections that continue to operate properly over time, the solder may need good electromigration resistance. As high current flows through the solder joints, electromigration may cause decreased performance or failure in a conductor due to voids or blockages in the metal structure caused by electron momentum. In general, small grain sizes may provide more channels for grain boundary diffusion to reduce electromigration resistance. In one embodiment, addition of Cu may increase the electromigration resistance of the Sn—In solder.

The Sn—In alloy with a small grain microstructure may provide benefits when used with a capillary type underfill material or with a no-flow underfill material. In particular, typical Sn-Ag based solders have melting points around 220 degrees Celsius, requiring a peak reflow temperature of about 230 degrees Celsius or higher. Current no-flow underfill materials may be prone to generating voids at such temperatures, which degrade the effectiveness of the underfill. An advantage of a Sn—In alloy over other such solders (e.g., Sn—Ag—Cu alloys) may be that the temperature required to reflow the Sn—In solder may be substantially less. In one embodiment of the present invention, the Sn—In solder may melt at about 195 degrees Celsius and a processing temperature of about 195 to 225 degrees Celsius may be used. In one embodiment a processing temperature of about 210 to 215 degrees Celsius may be used. The lower processing temperatures may provide less void space in the no-flow underfill as compared to a standard processing temperature of about 235 degrees Celsius for a Sn-Ag-Cu alloy.

The foregoing Sn—In alloy embodiments may be applied to other types of solder joints as well. For example, problems similar to the flip-chip CTE mismatch result in joint failures for BGA packages. In this instance, the CTE mismatch is between the package material, typically a ceramic or the like, and the circuit board to which it is attached, typically a multi-layer fiberglass. In general, the solders may be employed in bonding solderable materials having CTE mismatches. Another example includes bonding an integrated heatsink (IHS) to a die. In this instance, the solder may further perform the function of the thermal interface material used in conventional IHS to die couplings.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. An apparatus comprising:
a plurality of conductive contacts on at least one surface of a die; and
a substrate conductively coupled to at least one of the conductive contacts by a solder comprising tin and indium.

2. The apparatus of claim 1, wherein:
the solder comprises about 82 to 88 weight percent tin and about 12 to 18 weight percent indium.

3. The apparatus of claim 2, wherein:
the solder comprises less than about 3 weight percent of at least one of copper, silver, or nickel.

4. The apparatus of claim 3, wherein:
the solder comprises about 85 weight percent tin, about 14 weight percent indium, and about 1 weight percent copper.

5. The apparatus of claim 4, wherein:
the solder comprises a small grain microstructure to increase electromigration resistance.

6. The apparatus of claim 1, wherein:
the solder comprises a solder having a small grain microstructure.

7. The apparatus of claim 6, wherein:
the small grain microstructure comprises a small grain microstructure having grains averaging about 3 microns across.

8. The apparatus of claim 1, wherein:
the conductive contacts comprise copper.

9. The apparatus of claim 1, further comprising:
an underfill material between the die and the substrate.

10. The apparatus of claim 9, wherein:
the underfill material comprises at least one of a capillary underfill material or a no flow underfill material.

11. A method comprising:
heating a die and a substrate, the die including a plurality of conductive contacts on at least one surface thereof and the substrate including a plurality of solder bumps comprising tin and indium on at least one surface thereof, to a temperature above the melting point of the solder bumps;
contacting at least one of the conductive contacts with at least one of the solder bumps; and
cooling the die and the substrate to form at least one connection.

12. The method of claim 11, wherein:
the temperature is about 195 to 225 degrees Celsius.

13. The method of claim 11, wherein:
the temperature is about 210 to 215 degrees Celsius.

14. The method of claim 11, wherein:
cooling the die and the substrate comprises cooling the die and the substrate at a rate greater than about 3 degrees Celsius per second.

15. The method of claim 11, wherein:
cooling the die and the substrate comprises cooling the die and substrate using air cooling.

16. The method of claim 11, wherein:
the solder bumps comprise about 82 to 88 weight percent tin and about 12 to 18 weight percent indium.

17. The method of claim 16, wherein:
the solder bumps comprise less than about 3 weight percent of at least one of copper, silver, or nickel.

18. The method of claim 17, wherein:
the solder bumps comprise about 85 weight percent tin, about 14 weight percent indium, and about 1 weight percent copper.

19. The method of claim 11, wherein:
the connection comprises a small grain microstructure having small grains averaging approximately 3 microns across.

20. An alloy comprising:
about 82 to 88 weight percent tin; and
about 12 to 18 weight percent indium.

21. The alloy of claim 20, further comprising:
less than about 3 weight percent of at least one of copper, silver, or nickel.

22. The alloy of claim 21, wherein:
the weight percent of tin is about 85, the weight percent of indium is about 14 percent, and the weight percent of copper is about 1 percent.

23. An apparatus comprising:
a first component attached to a second component by a solder comprising tin and indium small grain microstructure.

24. The apparatus of claim 23, wherein:
the first component comprises a microelectronic package and the second component comprises a circuit board.

25. The apparatus of claim 23, wherein:
the first component comprises a microelectronic die and the second component comprises an integrated heat sink.

26. The apparatus of claim 23, wherein:
the first component comprises a microelectronic die and the second component comprises a package substrate.

27. The apparatus of claim 23, wherein:
the solder comprises about 85 weight percent tin, about 14 weight percent indium, and about 1 weight percent copper.
